(19) United States
(12) Patent Application Publication
(10) Pub. No.: US 2010/0248397 A1
(43) Pub. Date: Sep. 30, 2010

(54) High temperature susceptor having improved processing uniformity

(75) Inventors: Danny NEWMAN, Waterford, NY (US); Ronald NASMAN, Averill Park, NY (US); Richard Anthony DUFF, III, Glenville, NY (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/411,603

(22) Filed: Mar. 26, 2009

(51) Int. Cl. H01L 21/66; H01L 21/302; H01L 21/30

(52) U.S. Cl. 438/14; 118/725; 156/345.52; 438/706; 438/758; 257/E21.214; 257/E21.211; 257/E21.529

(57) ABSTRACT

A susceptor configured to be coupled to a material processing system is described. The susceptor comprises a substrate support comprising a central portion and an edge portion, wherein the central portion has a support surface configured to receive and support a substrate, and the edge portion extends beyond a peripheral edge of the substrate. The susceptor further comprises an edge reflector coupled to the edge portion of the substrate support and configured to partially or fully shield the peripheral edge of the substrate from radiative exchange with an outer region of the material processing system.

### BACKGROUND OF THE INVENTION

1. Field of the Invention

The invention relates to a susceptor configured to be coupled to a material processing system, and more particularly to a susceptor configured for improved processing uniformity.

2. Description of Related Art

It is known in semiconductor manufacturing and processing that various processes, including for example etch and deposition processes, depend significantly on the temperature of the substrate. For this reason, the ability to control the temperature of a substrate and, more specifically, uniformly control the temperature of the substrate is becoming an essential requirement of a semiconductor processing system. The temperature of a substrate is determined by many thermal interactions including, but not limited to, thermal exchange between a substrate and a substrate holder, thermal exchange between the substrate and its surrounding environment including other components of the processing system, thermal exchange between the substrate and/or substrate holder and the heat source(s) or sink(s) used to heat or cool the substrate and/or substrate holder, etc. Providing a proper temperature to the upper surface of the substrate holder may be utilized to control the temperature of the substrate.

### SUMMARY OF THE INVENTION

The invention relates to a susceptor configured to be coupled to a material processing system. The invention further relates to a susceptor configured for improved processing uniformity.

According to one embodiment, a susceptor configured to be coupled to a material processing system is described. The susceptor comprises a substrate support comprising a central portion and an edge portion, wherein the central portion has a support surface configured to receive and support a substrate, and the edge portion extends beyond a peripheral edge of the substrate. The susceptor further comprises an edge reflector coupled to the edge portion of the substrate support and configured to partially or fully shield the peripheral edge of the substrate from radiative exchange with an outer region of the material processing system.

According to another embodiment, a deposition system is described. The deposition system comprises a process chamber, a susceptor mounted within the process chamber, a lamp array configured to radiatively heat the susceptor, and a gas distribution system configured to introduce a process gas to the process chamber to facilitate film forming reactions at a surface of the substrate. The susceptor comprises a substrate support comprising a central portion and an edge portion, wherein the central portion has a support surface configured to receive and support a substrate, and the edge portion extends beyond a peripheral edge of the substrate. The susceptor further comprises an edge reflector coupled to the edge portion of the substrate support and configured to partially or fully shield the peripheral edge of the substrate from radiative exchange with an outer region of the material processing system.

According to yet another embodiment, a method of treating a substrate is described. The method comprises disposing a susceptor in a material processing system, the susceptor having: a substrate support configured to be coupled to a material processing system, the substrate support comprising a central portion and an edge portion, wherein the central portion has a support surface configured to receive and support a substrate, and the edge portion extends beyond a peripheral edge of the substrate; and an edge reflector coupled to the edge portion of the substrate support and configured to partially or fully shield the peripheral edge of the substrate from radiative exchange with an outer region of the material processing system, wherein a geometry of the susceptor is characterized by a height of the edge reflector being measured from a bottom surface of the substrate to a top surface of the edge reflector, a lateral spacing between the substrate and the edge reflector being measured from the peripheral edge of the substrate to an inner surface of the edge reflector, or an aspect ratio of the height to the lateral spacing, or a combination of two or more thereof. The method further comprises disposing a substrate on the susceptor in the material processing system, elevating a temperature of the susceptor to heat the substrate, measuring a property of the substrate or the susceptor or both at two or more locations, and adjusting the height, the lateral spacing, or the aspect ratio, or any combination of two or more thereof to reduce a variation of the property measured at the two or more locations.

### BRIEF DESCRIPTION OF THE DRAWINGS

In the accompanying drawings:

FIG. 1 is an illustration of a material processing system according to an embodiment;

FIG. 2A provides a top view of a susceptor according to an embodiment;

FIG. 2B provides a cross-sectional view of the susceptor depicted in FIG. 2A;

FIG. 2C shows an exploded, cross-sectional view of a portion of the susceptor depicted in FIG. 2B;

FIG. 2D provides another top view of the susceptor depicted in FIG. 2A;

FIG. 2E shows an exploded, cross-sectional view of another portion of the susceptor depicted in FIG. 2B;

FIG. 3A provides a cross-sectional view of a susceptor according to another embodiment;

FIG. 3B provides a cross-sectional view of a susceptor according to another embodiment;

FIG. 3C provides a cross-sectional view of a susceptor according to another embodiment;

FIG. 4 provides exemplary data for a deposition process;

FIG. 5 provides exemplary data for a deposition process; and

FIG. 6 provides a flow chart to illustrate a method of treating a substrate according to another embodiment.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

As described above, many processing parameters during various steps in semiconductor manufacturing play a vital role in the successful fabrication of robust, high performance electronic devices. A processing parameter of particular importance in a deposition process, an etch process, or other thermal process, is substrate temperature and its variation across the substrate. For example, chemical vapor deposition (CVD) is a technique conventionally used to deposit thin films, wherein substrate temperature is a critical processing parameter.

In a CVD process, a continuous stream of film precursor vapor is introduced to a process chamber containing a substrate, wherein the composition of the film precursor has the principal atomic or molecular species found in the film to be formed on the substrate. During this continuous process, the precursor vapor is chemisorbed on the surface of the substrate while it thermally decomposes and reacts with or without the presence of an additional gaseous component that assists the reduction of the chemisorbed material, thus, leaving behind the desired film.

Among other processing parameters, variations in substrate temperature may lead to variations in the deposition rate or film thickness. For example, in a kinetic-limited temperature regime, processing is typically characterized by a strong dependence of deposition rate on temperature. A kinetic-limited temperature regime refers to the range of deposition conditions where the deposition rate of a CVD process is limited by the kinetics of the chemical reactions at the substrate surface. Unlike the kinetic-limited temperature regime, a mass-transfer limited regime is normally observed at higher substrate temperatures and includes a range of deposition conditions where the deposition rate is limited by the flux of chemical reactants to the substrate surface. In either regime, the deposition rate depends on the substrate temperature; however, the level of dependence is greater for the kinetic-limited temperature regime.

Hence, the inventors recognize the desire to produce a spatially uniform substrate temperature profile or to tailor the substrate temperature profile to counter the effects of other non-uniform processing parameters. More specifically, the inventors have observed a reduction in the deposition rate (or deposited film thickness) at the edge of the substrate (to be discussed below), and they have attributed this reduction in the deposition rate to a corresponding measured reduction in the substrate temperature. The inventors believe the reduction in temperature to be associated with thermal losses at the substrate edge due to radiative interaction with the cooler chamber walls surrounding the substrate.

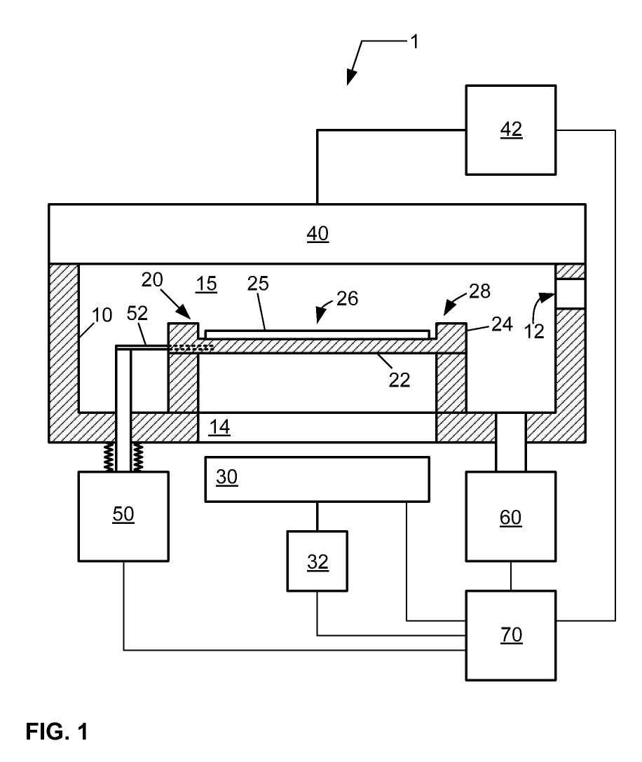

Therefore, referring now to the drawings, wherein like reference numerals designate identical or corresponding parts throughout the several views, FIG. 1 presents a material processing system 1 according to an embodiment. The material processing system 1 comprises a process chamber 10, a susceptor 20 mounted in the process chamber 10 and configured to support a substrate 25 within a process space 15, a heat source 30 configured to elevate a temperature of the susceptor 20, and a gas distribution system 40 configured to introduce a process gas to the process chamber 10 to facilitate film forming reactions at a surface of the substrate 25.

Additionally, the material processing system 1 comprises a vacuum pumping system 60 coupled to the process chamber 10 and configured to evacuate the process chamber 10. Furthermore, a controller 70 is coupled to the process chamber 10, the susceptor 20, the heat source 30, the gas distribution system 40, and the vacuum pumping system 60, and may be configured to monitor, adjust and control the substrate temperature as will be further discussed below.

In the illustrated embodiment depicted in FIG. 1, the material processing system 1 includes a deposition system and, more specifically, a thermal CVD (chemical vapor deposition) system. However, the susceptor 20 may be utilized in other processing systems. For example, material processing system 1 may include an etch system configured to facilitate dry plasma etching, or, alternatively, dry non-plasma etching. Alternately, the material processing system 1 includes a photo-resist coating chamber such as a heating/cooling module in a photo-resist spin coating system that may be utilized for post-adhesion bake (PAB) or post-exposure bake (PEB), etc.; a photo-resist patterning chamber such as a photo-lithography system; a dielectric coating chamber such as a spin-on-glass (SOG) or spin-on-dielectric (SOD) system; a deposition chamber such as a vapor deposition system, chemical vapor deposition (CVD) system, plasma enhanced CVD (PECVD) system, atomic layer deposition (ALD) system, plasma enhanced ALD (PEALD) system, or a physical vapor deposition (PVD) system; or a rapid thermal processing (RTP) chamber such as a RTP system for thermal annealing.

The susceptor 20 comprises a substrate support 22 comprising a central portion 26 and an edge portion 28, wherein the central portion 26 has a support surface configured to receive and support substrate 25, and the edge portion 28 extends beyond a peripheral edge of the substrate 25. The susceptor 20 further comprises an edge reflector 24 coupled to the edge portion of the substrate support 22 and configured to partially or fully shield the peripheral edge of the substrate 25 from radiative exchange with an outer region of the material processing system 1. For example, the outer region of material processing system 1 may include the process chamber 10. Further, in addition to shielding the edge of substrate 25, the edge reflector 24 may influence the substrate temperature at the edge of substrate 25 via radiative heating (i.e., if the temperature of the edge reflector 24 exceeds the substrate temperature at the edge of substrate 25).

The heat source 30 may comprise one or more lamps, such as a lamp array, configured to radiatively heat the susceptor 20 by illuminating a backside of susceptor 20 through an optically transparent window 14. The one or more lamps may comprise a tungsten-halogen lamp. Additionally, the one or more lamps may be coupled to a drive system 32 configured to rotate and/or translate the one or more lamps in order to adjust and/or improve radiative heating of the susceptor 20. Furthermore, the one or more lamps may be aligned relative to one another in such a way as to adjust and/or improve radiative heating of the susceptor 20.

The gas distribution system 40 may comprise a showerhead gas injection system having a gas distribution assembly, and one or more gas distribution plates coupled to the gas distribution assembly and configured to form one or more gas distribution plenums. Although not shown, the one or more gas distribution plenums may comprise one or more gas distribution baffle plates. The one or more gas distribution plates further comprise one or more gas distribution orifices to distribute a process gas from the one or more gas distribution plenums to the process space 15 within process chamber 10. Additionally, the gas distribution system 40 is coupled to a process gas supply system 42.

The process gas supply system 42 is configured to supply the process gas, which may include one or more film precursors, one or more reduction gases, one or more carrier gases, one or more inert gases, etc., to the gas distribution system 40. Further, the one or more film precursors may include a vapor derived from a liquid or solid-phase source. For example, the process gas supply system 42 may include a precursor vaporization system configured to evaporate a precursor in a liquid-phase or sublime a precursor in a solid-phase to form precursor vapor. The terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas.

Furthermore, the material processing system 1 comprises a lifting assembly 50 comprising three or more lifting elements 52 configured to vertically translate substrate 25 to and from the support surface of substrate support 22, and to and from a horizontal plane in process chamber 10 where substrate 25 may be transferred into and out of process chamber 10 through transfer slot 12. As shown in FIG. 1, each of the three or more lifting elements 52 may extend laterally through an opening in the edge reflector 24 to a recess positioned below the peripheral edge of substrate 25 in substrate support 22.

Alternatively, the lifting assembly may comprise three or more lift pins (not shown) configured to vertically translate substrate 25 to and from the support surface of substrate support 22, and to and from a horizontal plane in process chamber 10 where substrate 25 may be transferred into and out of process chamber 10 through transfer slot 12. Although not shown, the three or more lift pins may extend through openings in substrate support 22 and contact a bottom surface of substrate 25 when elevating and lowering substrate 25.

Vacuum pumping system 60 may include a turbo-molecular vacuum pump (TMP) capable of a pumping speed up to about 5000 liters per second (and greater) and a gate valve for throttling the chamber pressure. In conventional processing devices utilized for vacuum processing, a 1000 to 3000 liter per second TMP can be employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the process chamber 10. The pressure measuring device can be, for example, a Type 628B Baratron absolute capacitance manometer commercially available from MKS Instruments, Inc. (Andover, Mass.).

Controller 70 comprises a microprocessor, memory, and a digital I/O port capable of generating control voltages sufficient to communicate and activate inputs to material processing system 1 as well as monitor outputs from material processing system 1. Moreover, controller 70 can be coupled to and can exchange information with heat source 30, drive system 32, gas supply system 42, substrate lifting assembly 50, vacuum pumping system 60, and/or one or more temperature measurement devices (not shown). For example, a program stored in the memory can be utilized to activate the inputs to the aforementioned components of material processing system 1 according to a process recipe in order to perform a vapor deposition process on substrate 25.

Controller 70 can be locally located relative to the material processing system 1, or it can be remotely located relative to the processing system 1a. For example, controller 70 can exchange data with material processing system 1 using a direct connection, an intranet, and/or the internet. Controller 70 can be coupled to an intranet at, for example, a customer site (i.e., a device maker, etc.), or it can be coupled to an intranet at, for example, a vendor site (i.e., an equipment manufacturer). Alternatively or additionally, controller 70 can be coupled to the internet. Furthermore, another computer (i.e., controller, server, etc.) can access controller 70 to exchange data via a direct connection, an intranet, and/or the internet.

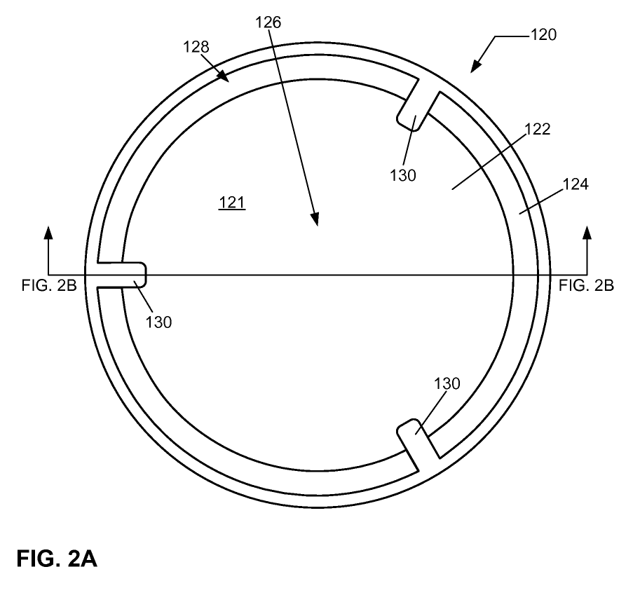

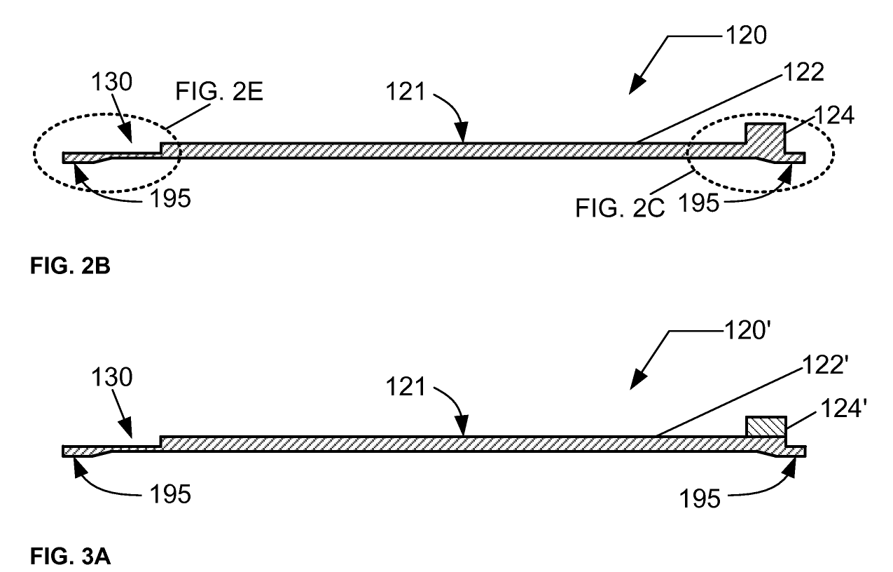

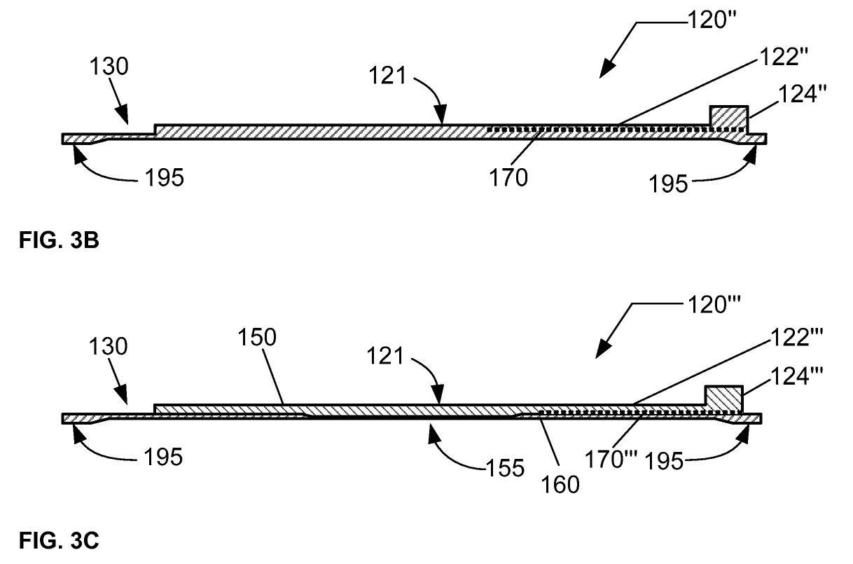

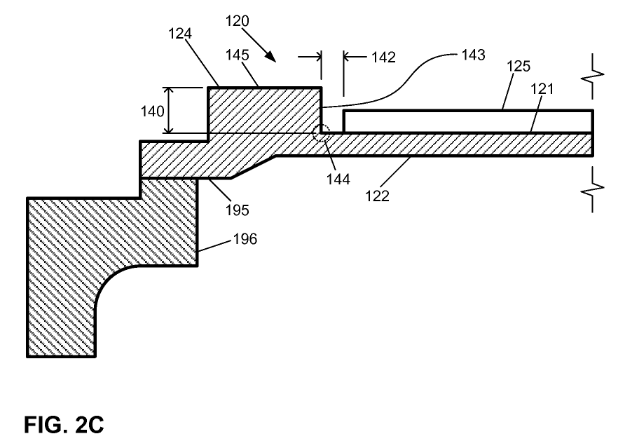

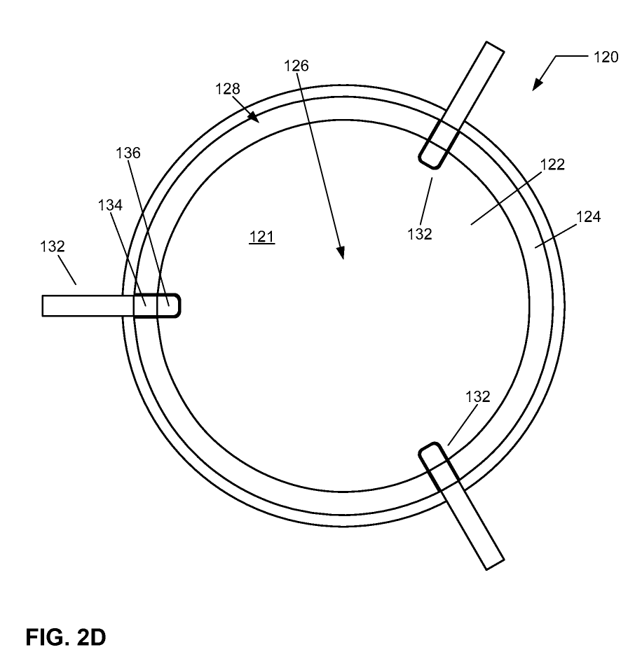

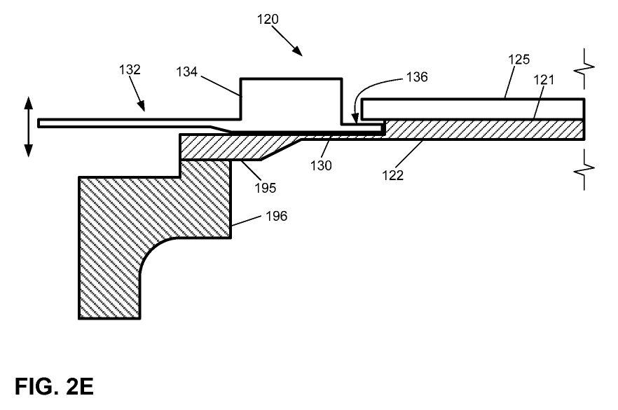

Referring now to FIGS. 2A through 2E, several views, including top views and cross-sectional views, of a susceptor 120 are provided according to an embodiment. FIGS. 2A and 2D provide a top view of susceptor 120 with and without the presence of lifting elements 132, respectively. FIG. 2B provides a cross-sectional view of susceptor 120 along the section line indicated in FIG. 2A. FIGS. 2C and 2D provide exploded cross-sectional views of different regions of susceptor 120 as indicated in FIG. 2B.

The susceptor 120 comprises a substrate support 122 comprising a central portion 126 and an edge portion 128, wherein the central portion 126 has a support surface 121 configured to receive and support a substrate 125, and the edge portion 128 extends beyond a peripheral edge of substrate 125. The susceptor 120 also comprises an edge reflector 124 coupled to the edge portion of the substrate support 122 and configured to partially or fully shield the peripheral edge of substrate from radiative exchange with an outer region of a material processing system, such as material processing system 1 in FIG. 1). In addition to shielding the edge of the substrate, the edge reflector 124 may influence the substrate temperature at the edge of the substrate via radiative heating (i.e., if the temperature of the edge reflector 124 exceeds the substrate temperature at the edge of the substrate). The susceptor 120 comprises a substrate support 122 configured for supporting a substrate having a circular geometry. However, the substrate support may be configured for other geometries including, for example, rectangular geometries.

As illustrated in FIG. 2C, an exploded cross-section view of susceptor 120 is provided. The susceptor 120 may be mounted within a process chamber, and supported at a base surface 195 by a chamber support structure 196. The susceptor 120 may or may not be affixed and/or fastened to the chamber support structure 196.

Additionally, as illustrated in FIG. 2C, the geometry of the edge reflector 124 may be characterized by a height 140 of the edge reflector 124, a lateral spacing 142 between the edge reflector 124 and the substrate 125, an orientation of an inner surface 143 of edge reflector 124, or a shape of corner region 144, or any combination of two or more thereof. The height 140 may be measured from a bottom surface of substrate 125 (or the support surface 121) to a top surface 145 of edge reflector 124. The lateral spacing 142 may be measured from a peripheral edge of substrate 125 to an inner surface 143 of edge reflector 124.

The height 140 of edge reflector 124 may be equivalent to a thickness of substrate 125. Alternatively, the height 140 may be about 1 mm (millimeter) or greater. Alternatively, the height 140 may be about 2 mm or greater. Alternatively, the height 140 may be about 3 mm or greater. Alternatively, the height 140 may be about 4 mm or greater. Alternatively, the height 140 may be about 5 mm or greater.

The orientation of the inner surface 143 may be such that it is substantially perpendicular to support surface 121. Further, the geometry of corner region 144 may be such that any fillet and/or angled corner/bevel is substantially reduced, eliminated, and/or minimized.

The lateral spacing 142 between edge reflector 124 and substrate 125 may be 2 mm or less. Alternatively, the lateral spacing 142 between edge reflector 124 and substrate 125 may be 1 mm or less. Alternatively, the lateral spacing 142 between edge reflector 124 and substrate 125 may be 0.5 mm or less.

The geometry of the edge reflector 124 may further be characterized by an aspect ratio of the height 140 of edge reflector 124 to the lateral spacing 142 between edge reflector 124 and substrate 125. The aspect ratio may be greater than or equal to about 1:1. Alternatively, the aspect ratio may be greater than or equal to about 2:1. Alternatively, the aspect ratio may be greater than or equal to about 4:1.

As shown in FIG. 2B, the susceptor 120 may comprise a monolithic component. For example, the substrate support 122 and the edge reflector 124 are fabricated from a single piece of material, or are adjoined and/or fused via a sintering process, a brazing process, or a welding process. The substrate support 122 or the edge reflector 124 or both may comprise a ceramic or a metal coated with a ceramic. The substrate support 122 or the edge reflector 124 or both may comprise an oxide, a nitride, a carbide, or any combination of two or more thereof. For example, the substrate support 122 or the edge reflector 124 may be composed of silicon carbide.

Alternatively, as shown in FIG. 3A, a susceptor 120′ may comprise multiple components. For example, susceptor 120′ may comprise a substrate support 122′ and an edge reflector 124′ that are separate and distinct components. Furthermore, for example, edge reflector 124′ may rest atop substrate support 122″. The substrate support 122′ and the edge reflector 124′ may comprise the same material composition. Alternatively, the substrate support 122′ and the edge reflector 124′ may comprise different material compositions.

According to another embodiment as shown in FIG. 3B, a susceptor 120″ may comprise one or more temperature measurement devices 170 inserted therein and configured to measure a substrate temperature, or a susceptor temperature, or both a substrate temperature and a susceptor temperature. The one or more temperature measurement devices 170 may be inserted into a conduit drilled laterally into susceptor 120″.

The one or more temperature measurement devices 170 may include an optical fiber thermometer, an optical pyrometer, a band-edge temperature measurement system as described in pending U.S. patent application Ser. No. 10/168,544, filed on Jul. 2, 2002, the contents of which are incorporated herein by reference in their entirety, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

According to yet another embodiment as shown in FIG. 3C, a susceptor 120″′ may comprise a substrate support 122″′ and an edge reflector 124″′, wherein the substrate support 122″′ comprises an upper support plate 150 and a lower base plate 160, separate from one another. Additionally, the upper support plate 150 or the lower base plate 160 or both the upper support plate 150 and the lower base plate 160 comprise an alignment feature 155 configured to align the upper support plate 150 and the lower base plate 160 with one another. For example, the alignment feature 155 may include a surface recess or groove formed in the lower base plate 160 and a surface protrusion formed in the upper support plate 150, wherein the surface recess or groove is configured to mate with the surface protrusion, thus adjoining and aligning the upper support plate 150 and the lower base plate 160.

Additionally, as shown in FIG. 3C, the susceptor 120″′ may comprise one or more temperature measurement devices 170″′ inserted between the upper support plate 150 and the lower base plate 160. For example, the one or more temperature measurement devices 170″′ may reside in a groove or channel formed in a bottom surface of the upper support plate 150, or a top surface of the lower base plate 160, or both the bottom surface of the upper support plate 150 and the top surface of the lower base plate 160.

Referring again to FIGS. 2A through 2E, a lifting assembly comprising three or more lifting elements 132 (FIGS. 2D, 2E) is shown that is configured to vertically translate substrate 125 (FIGS. 2C, 2E) to and from the support surface 121 (FIGS. 2A-2E) of substrate support 122 (FIGS. 2A-2E). Each of the three or more lifting elements 132 may extend laterally through an opening in the edge reflector 124 to a recess 130 (FIGS. 2B, 2E) positioned below the peripheral edge of substrate 125 in substrate support 122. Furthermore, each of the three or more lifting elements 132 comprises a lifting support surface 136 (FIGS. 2D, 2E) configured to contact a bottom surface of substrate 125 when lifting substrate 125, and a reflector portion 134 (FIGS. 2D, 2E) that aligns and fills the opening in the edge reflector 124 to create a continuous reflector surrounding substrate 125 when not lifting substrate 125.

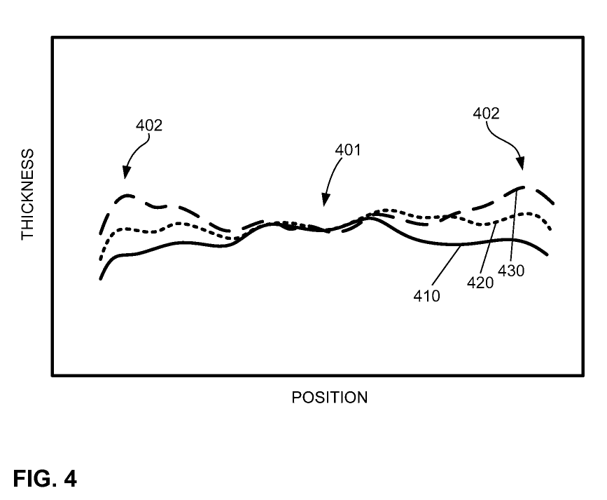

Referring now to FIG. 4, exemplary data is provided for a deposition process. A layer of poly-crystalline silicon (poly-silicon) is deposited on a substrate using a thermal CVD process. The substrate is disposed on a susceptor, as described above, and a film precursor containing silane is introduced to a process space above the substrate while the substrate is elevated to approximately 640 degrees C. The susceptor comprises a substrate support and edge reflector having a height of 3 mm

As shown in FIG. 4, a thickness of the poly-silicon layer is provided as a function of position on the substrate, wherein reference numeral 401 indicates the central portion of the substrate and reference numeral 402 indicates the edge portions of the substrate. Three different thickness profiles 410, 420, 430 are shown. Each thickness profile is acquired for a different lateral spacing between the edge reflector and the peripheral edge of the substrate. The order of measurement of the three different thickness profiled proceeds from profile 410 to profile 420 to profile 430, and this order corresponds to a reduction in the lateral spacing. As the lateral spacing is reduced, the thickness of the deposited film increases at the edge portion of the substrate.

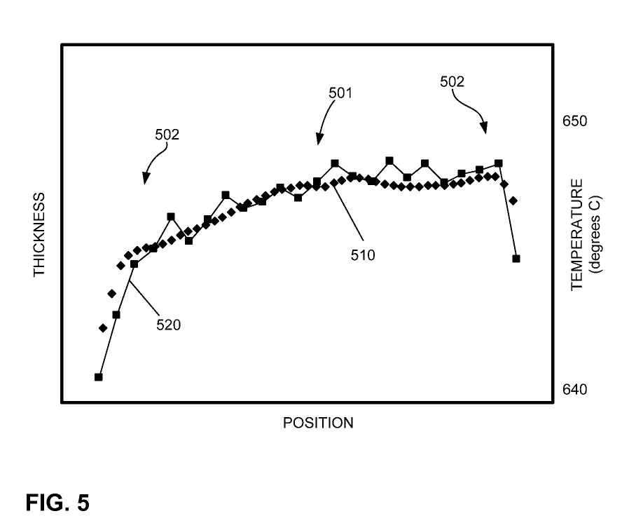

Turning now to FIG. 5, measurements of substrate temperature are provided along with measurements of the deposited film thickness. FIG. 5 provides a measured film thickness profile and temperature profile for a thermal CVD process similar to that described above. As observed in FIG. 5, the spatial variation of the film thickness closely correlates with the spatial variation of substrate temperature.

The inventors have observed several trends for affecting changes in the substrate temperature and, in turn, the film thickness or deposition rate through changes in the design of the edge reflector. While holding other geometrical parameters constant, a decrease in the lateral spacing affects an increase of the substrate temperature at the peripheral edge of substrate. Additionally, while holding other geometrical parameters constant, an increase in the height affects an increase of the substrate temperature at the peripheral edge of substrate. Furthermore, the inner surface of the edge reflector may be designed to be substantially perpendicular to the support surface of the substrate support, and the corner formed between the inner surface of the edge reflector and the support surface may be fabricated in such a way to substantially reduce, eliminate, and/or minimize any fillet or angled corner/bevel, etc.

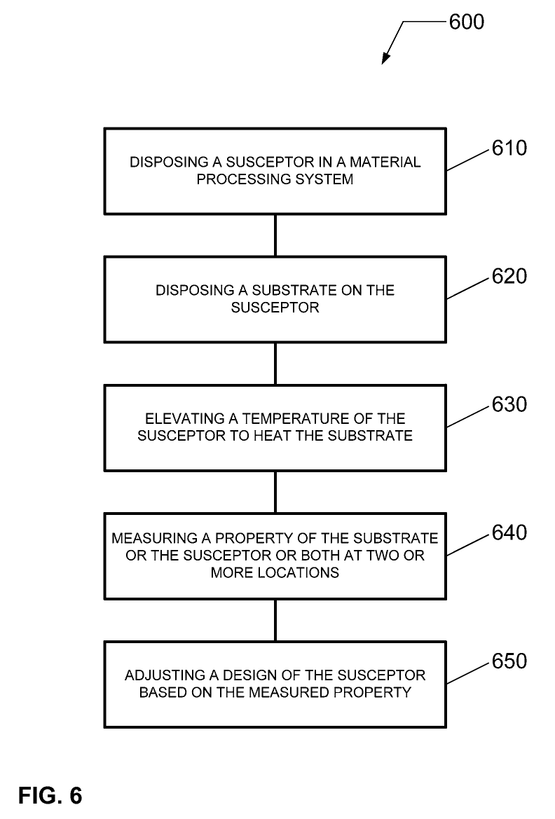

In FIG. 6, a method of treating a substrate is described according to another embodiment. The method comprises a flow chart 600 beginning in 610 with disposing a susceptor in a material processing system. The susceptor may include any one of the susceptors described above in FIGS. 1 through 3.

For example, the susceptor comprises a substrate support configured to be coupled to the material processing system, wherein the substrate support comprises a central portion and an edge portion, and wherein the central portion has a support surface configured to receive and support a substrate and the edge portion extends beyond a peripheral edge of the substrate. The susceptor further comprises an edge reflector coupled to the edge portion of the substrate support and configured to partially or fully shield the peripheral edge of the substrate from radiative exchange with an outer region of the material processing system. The geometry of the susceptor is characterized by a height of the edge reflector being measured from a bottom surface of the substrate to a top surface of the edge reflector, a lateral spacing between the substrate and the edge reflector being measured from the peripheral edge of the substrate to an inner surface of the edge reflector, or an aspect ratio of the height to the lateral spacing, or a combination of two or more thereof.

In 620, a substrate is disposed on the susceptor in the material processing system.

In 630, a temperature of the susceptor is elevated to heat the substrate. The substrate may be heated to perform a deposition process such as a CVD process as described above, an etching process, or another thermal process.

In 640, a property of the substrate, the susceptor, or both the substrate and susceptor is measured at two or more locations. The measured property may include a temperature of the substrate, a temperature of the susceptor, a film thickness for a thin film formed on the substrate, a deposition rate for a thin film formed on the substrate, an etch amount for material removed from the substrate, or an etch rate for material removed from the substrate, or any combination of two or more thereof.

In 650, a design of the susceptor is adjusted based on the measured property. For example, the adjustment of the design of the susceptor may include adjusting a height of the edge reflector being measured from a bottom surface of the substrate to a top surface of the edge reflector, a lateral spacing between the substrate and the edge reflector being measured from the peripheral edge of the substrate to an inner surface of the edge reflector, or an aspect ratio of the height to the lateral spacing, or a combination of two or more thereof. Using the trends observed above as a guideline, one or more of these geometrical parameters may be adjusted to achieve a desired change in the measured property.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A susceptor, comprising:
a substrate support configured to be coupled to a material processing system, said substrate support comprising a central portion and an edge portion, wherein said central portion has a support surface configured to receive and support a substrate, and said edge portion extends beyond a peripheral edge of said substrate; and
an edge reflector coupled to said edge portion of said substrate support and configured to partially or fully shield said peripheral edge of said substrate from radiative exchange with an outer region of said material processing system.

2. The susceptor of claim 1, wherein an aspect ratio of a height of said edge reflector to a lateral spacing between said edge reflector and said substrate is greater than or equal to about 1:1, said height being measured from a bottom surface of said substrate to a top surface of said edge reflector, and said lateral spacing being measured from said peripheral edge of said substrate to an inner surface of said edge reflector.

3. The susceptor of claim 2, wherein said aspect ratio is greater than or equal to about 2:1.

4. The susceptor of claim 2, wherein said aspect ratio is greater than or equal to about 4:1.

5. The susceptor of claim 1, wherein said substrate support comprises a circular geometry, or rectangular geometry.

6. The susceptor of claim 1, wherein said substrate support and said edge reflector are a monolithic component.

7. The susceptor of claim 1, wherein said substrate support and said edge reflector are separate and distinct components.

8. The susceptor of claim 7, wherein said substrate support and said edge reflector comprise the same material composition.

9. The susceptor of claim 1, wherein said substrate support and said edge reflector are composed of a ceramic or a metal coated with a ceramic.

10. The susceptor of claim 1, wherein said substrate support and said edge reflector are composed of an oxide, a nitride, a carbide, or any combination of two or more thereof.

11. The susceptor of claim 1, further comprising:
a lifting assembly comprising three or more lift pins configured to vertically translate said substrate to and from said support surface of said substrate support, said three or more lift pins extend through openings in said substrate support and contact a bottom surface of said substrate when elevating and lowering said substrate.

12. The susceptor of claim 1, further comprising:
a lifting assembly comprising three or more lifting elements configured to vertically translate said substrate to and from said support surface of said substrate support,
wherein each of said three or more lifting elements extends laterally through an opening in said edge reflector to a recess positioned below said peripheral edge of said substrate in said substrate support, and
wherein each of said three or more lifting elements comprises:
a lifting support surface configured to contact a bottom surface of said substrate when lifting said substrate; and
a reflector portion that aligns and fills said opening in said edge reflector to create a continuous reflector surrounding said substrate when not lifting said substrate.

13. The susceptor of claim 1, wherein said substrate support comprises an upper support plate and a lower base plate, separate from one another, and wherein said upper support plate or said lower base plate or both said upper support plate and said lower base plate comprise an alignment feature configured to align said upper support plate and said lower base plate with one another.

14. The susceptor of claim 13, further comprises:
a temperature measurement device configured to be inserted between said upper support plate and said lower base plate.

15. The susceptor of claim 1, wherein said material processing system comprises an etching system, a deposition system, or a thermal treatment system.

16. A deposition system, comprising:
a process chamber;
a susceptor mounted within said process chamber, said susceptor comprising:
a substrate support configured to be coupled to a material processing system, said substrate support comprising a central portion and an edge portion, wherein said central portion has a support surface configured to receive and support a substrate, and said edge portion extends beyond a peripheral edge of said substrate, and
an edge reflector coupled to said edge portion of said substrate support and configured to partially or fully shield said peripheral edge of said substrate from radiative exchange with an outer region of said process chamber;
a lamp array configured to radiatively heat said susceptor; and
a gas distribution system configured to introduce a process gas to said process chamber to facilitate film forming reactions at a surface of said substrate.

17. The deposition system of claim 16, wherein said lamp array is located below said substrate support and is configured to rotate.

18. The deposition system of claim 16, further comprising:
a lifting assembly comprising three or more lifting elements configured to vertically translate said substrate to and from said support surface of said substrate support,
wherein each of said three or more lifting elements extends laterally through an opening in said edge reflector to a recess positioned below said peripheral edge of said substrate in said substrate support, and
wherein each of said three or more lifting elements comprises:
a lifting support surface configured to contact a bottom surface of said substrate when lifting said substrate; and
a reflector portion that aligns and fills said opening in said edge reflector to create a continuous reflector surrounding said substrate when not lifting said substrate.

19. A method of treating a substrate, comprising:
disposing a susceptor in a material processing system, said susceptor having:
a substrate support configured to be coupled to a material processing system, said substrate support comprising a central portion and an edge portion, wherein said central portion has a support surface configured to receive and support a substrate, and said edge portion extends beyond a peripheral edge of said substrate; and
an edge reflector coupled to said edge portion of said substrate support and configured to partially or fully shield said peripheral edge of said substrate from radiative exchange with an outer region of said material processing system,
wherein a geometry of said susceptor is characterized by a height of said edge reflector being measured from a bottom surface of said substrate to a top surface of said edge reflector, a lateral spacing between said substrate and said edge reflector being measured from said peripheral edge of said substrate to an inner surface of said edge reflector, or an aspect ratio of said height to said lateral spacing, or a combination of two or more thereof;
disposing a substrate on said susceptor in said material processing system;
elevating a temperature of said susceptor to heat said substrate;
measuring a property of said substrate or said susceptor or both at two or more locations; and
adjusting said height, said lateral spacing, or said aspect ratio, or any combination of two or more thereof to reduce a variation of said property measured at said two or more locations.

20. The method of claim 19, wherein said property comprises a temperature of said substrate, a temperature of said susceptor, a film thickness for a thin film formed on said substrate, a deposition rate for a thin film formed on said substrate, an etch amount for material removed from said substrate, or an etch rate for material removed from said substrate, or any combination of two or more thereof.
